(19) United States
(12) Patent Application Publication
(10) Pub. No.: US 2006/0073687 A1
(43) Pub. Date: Apr. 6, 2006

(54) Method for maskless fabrication of self-aligned structures comprising a metal oxide

(75) Inventors: Rudolf Johan Maria Vullers, Eindhoven (NL); Bokke Johannes Feenstra, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V., Eindhoven (SE)

(21) Appl. No.: 10/540,709

(22) PCT Filed: Dec. 3, 2003
(86) PCT No.: PCT/IB03/05692

§ 371 Date: Jun. 24, 2005

(30) Foreign Application Priority Data
Dec. 30, 2002 (EP) 02080573.5

(51) Int. Cl. H01L 21/20

(52) U.S. Cl. 438/584

(57) ABSTRACT

The present invention describes a method for fabricating micro-devices comprising aluminumoxide structures without the need for an extra lithographical processing step. So, no extra mask is needed. It appears that under certain circumstances, aluminumoxide walls arise in the etching process, just above sloped walls of underlying metal structures. The fact that the walls of the metal structures are sloped, is essential here. Using the method according to the invention, aluminumoxide structures can be fabricated that are aligned exactly above the sloped walls of the metal structure. These aligned aluminumoxide structures can be used as walls in for example microfluidic channels, electrowetting displays, electrophoretic displays or field emitting displays.

### FIELD OF THE INVENTION

The present invention relates to a method of manufacturing a micro device on a substrate, like for example a semiconductor device. It also relates to a device fabricated by using such a method.

### STATE OF THE ART

In semiconductor fabrication, wet etching of aluminumoxide (alumina) is performed using wet etching chemicals like phosphoric acid (H₃PO₄) or hot strong bases like KOH, NaOH or Ca(OH)₂. In order to produce a structure on a sample, a selectively formed photoresist layer is used to mask specific areas on the sample, before etching the aluminumoxide, see for example patent U.S. Pat. No. 3,935,083.

The selectively formed photoresist layer is produced using a lithographic process, in which the photoresists is hardened. Afterwards, the non-hardened photoresist is removed in a stripping process. During the lithographic process, a mask must be aligned on the sample. Imprecise alignment of the mask may result in erroneous position of produced features.

### SUMMARY OF THE INVENTION

It is an object of the present invention to fabricate structures in an aluminumoxide layer of a device, with fewer lithographic processing steps than the presently known methods. Therefore, the invention relates to a method of manufacturing a device on a substrate, comprising:
Depositing a metal layer with a thickness x on the substrate;
Depositing a resist layer;
Patterning of the resist layer using lithographic techniques, leaving a resist pattern with negative slopes;
Depositing metal using a galvanic process;
Removing the resist pattern;
Sputter etching of the metal and the metal layer to remove said metal layer and provide a metal structure with sloped sidewalls;
Depositing a first layer of metal oxide; in particular aluminumoxide
Forming self-aligned structures above the sloped sidewalls of the metal structure by etching the first layer of aluminumoxide until a predetermined thickness of aluminumoxide above the metal structure remains.

Using the method according to the invention, metal oxide, notably aluminumoxide structures can easily be fabricated without the need for an extra lithographical processing step. Furthermore, the metal oxide structures, notably aluminumoxide structures are perfectly aligned above the sidewalls of the metal structures (i.e. self-alignment).

In an embodiment, the invention relates to a method as described above, characterized in that the depositing of the first layer of metal oxide, such as aluminumoxide is directly followed by:
Depositing a non-transparent film on top of the first layer of metal oxide, notably aluminumoxide;
Depositing a second layer of metal oxide, e.g. aluminumoxide on top of the non-transparent film;
Polishing the metal oxide, e.g. aluminumoxide until all non-transparent film is removed.

By inserting these three steps, the surface of the metal oxide, e.g. aluminumoxide layer is flattened. The following steps, already described above, will result in a device, wherein the metal oxide e.g. aluminumoxide surface has the same level in areas with and without a metal structure underneath. This is useful in cases where other lithographic processes will follow.

In another embodiment, the method is characterized in that before the depositing of the first layer of aluminumoxide, an oxide layer is deposited, in such a way that the oxide layer fills gaps between parts of the metal structure. In this way, walls are avoided at junctions of electrodes, and as a result, uninterrupted channels without blockades are created.

In an embodiment, the method is characterized in that that the device is a reflective electrowetting or electrophoretic display.

In yet another embodiment, the method is characterized in that the device is a Field Emitting Device (FED).

The invention also relates to a microfluidic device, a microwetting display, a microphoretic display and a field emitting display fabricated by the respective methods described above.

### BRIEF DESCRIPTION OF THE DRAWINGS

Below, the invention will be explained with reference to some drawings, which are intended for illustration purposes only and not to limit the scope of protection as defined in the accompanying claims.

FIG. 1 shows schematically a cross-sectional view of a device after fabricating a metal structure according to the method of the present invention;

FIG. 2 shows schematically a cross-sectional view of a device after deposition of d nm aluminumoxide on top of the metal structure according to a first embodiment of the present invention;

FIG. 3 shows schematically a cross-sectional view of a device after etching the aluminumoxide according to the method of the present invention;

FIG. 4 shows schematically a cross-sectional view of a device after deposition of aluminumoxide on top of a metal structure according to a second embodiment of the present invention;

FIG. 5 shows schematically a cross-sectional view of a device after deposition of a non-transparent layer and a thin aluminumoxide layer on top of the thick aluminumoxide layer according to a second embodiment of the present invention;

FIG. 6 shows schematically a cross-sectional view of a device after polishing the device just until all of the non-transparent layer is gone;

FIG. 7 shows schematically a cross-sectional view of a device after etching the aluminumoxide according to the method of the present invention;

FIG. 8 shows a top view of two separated electrodes;

FIG. 9 shows three cross-sectional views in a first direction, of a gap between two electrodes of a device, during deposition of an extra oxide layer and a thick aluminumoxide layer on top of the electrodes, according to an embodiment of the present invention;

FIG. 10 shows three cross-sectional views in a second direction, of a gap between two electrodes of a device, during deposition of an extra oxide layer and a thick aluminumoxide layer on top of the electrodes, according to an embodiment of the present invention.

FIG. 11 shows a top view of a metal structure comprising a junction with four electrodes.

FIG. 12 shows a top view of the channels above the junction of FIG. 11, resulting from an embodiment of the method according to the invention.

FIG. 13 shows schematically a cross-sectional and top view of a device fabricated according to the invention, having an additional metal layer deposited after the etching of the aluminumoxide, wherein the top and bottom electrode are not electrically connected.

### DESCRIPTION OF PREFERRED EMBODIMENTS

This invention is based upon the experimental observation of different etching and polishing behavior of aluminumoxide on top of sloped Cu structures. This effect was observed after the following processing steps:
1. Cu structures with sloped sidewalls were formed (thickness 4 μm, width between 5 and 10 μm);
2. These Cu structures were covered by aluminumoxide of thickness 10 μm;
3. Subsequently, the oxide is polished chemical/mechanically, leaving a flat substrate;
4. The oxide is etched, until the remaining thickness of the oxide above the Cu is 1 to 2 μm.

After step 4, the appearance of non-etched parts (pillars) was observed, exactly at the positions were the sidewalls of the Cu structures were sloped. Before explaining the appearance of the pillars, first something about the deposited aluminumoxide is discussed in the following.

The oxide is deposited by sputtering from a stoichometric Al₂O₃ target (the sputter conditions are listed in table 1).

TABLE 1
process parameters

| Parameter | Value | |
|---|---|---|
| Target | Al₂O₃ | |
| Pressure | 1 10⁻⁶ | bar |
| Ar gas flow | 37 | sccm |
| Sample bias | 70 | V |
| RF power | 400 | W |

The growth and structure of thin films are dependent on numerous parameters. The most important being: Deposition technique, deposition rate, geometry, contamination, dissociation, particle energy, substrate preparation, and substrate temperature. Clearly, the observed effect of slower etching is due to geometry reasons. The existence of sloped walls causes a geometric effect while sputtering. Due to the sloped walls, there is a difference in incident angle for the incoming sputtered atoms. Departures from normal incidence may introduce directional mobility effects at the substrate which influence nucleation and subsequent growth. This in turn might have an effect on the film structure (amorphous or crystalline), the film composition (Al₂O₃₋ₓ), the film porosity or the stress in the film. All these factors effect the etch rate of the formed films. A detailed treatment on the effect of sputtering parameters and thin film growth can be found in Thin Film Technology, R. W. Berry, P. M. Hall, and M. T. Harris, Princeton, N.Y., 1968, and in Basic Problems in Thin Film Physics, R. Niedermayer, and H. Mayer, Göttingen, 1966.

In the method according to the invention, the aluminiumoxide, formed on the sloped walls, etches much slower than the oxide on the substrate and on the flat part of the Cu structures. From the discussion above, one of the possible explanations can be a difference in stoichometry. Experimentally it was found that stoichometric Al₂O₃ has a very low etch rate, while the aluminumoxide grown on the substrate under the process parameters listed in table 1 etches at a high rate in H₃PO₄ (100 nm/min). A possible explanation for the experimentally found effect might thus be that normally the sputtered film consists of Al₂O₃₋ₓ, with 0<x<1, while the oxide formed on the sloped walls will be closer to Al₂O₃.

Below, the method according to the invention will be illustrated by some examples.

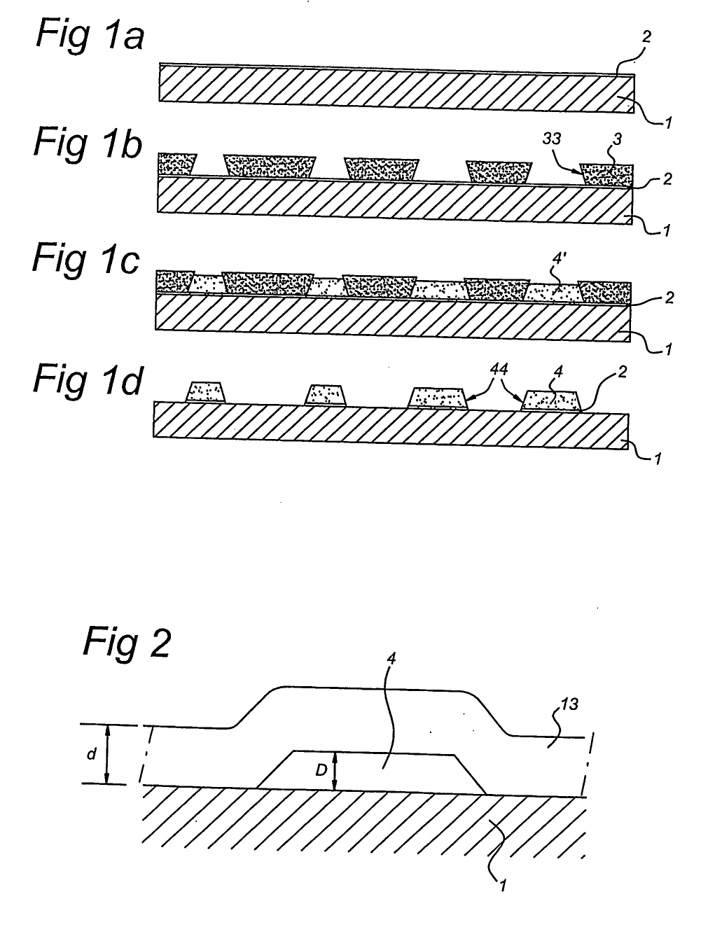

In FIG. 1 a cross-sectional view of a device is shown during several steps of the fabrication of metal structures according to the method of the present invention. First, see FIG. 1a, a thin metal layer 2 (i.e. “the plating base”), having a thickness of x nm, is deposited (e.g. sputtered) onto an insulating substrate 1. Here, x is about 200 to 300 nm. Next, see FIG. 1b, a resist pattern 3 is formed on top of the thin metal layer 2, with conventional lithographic techniques. It is now essential that slopes 33 of the resist pattern 3 are negative. Then, see FIG. 1c, a metal pattern 4′ is fabricated using a galvanic process. The galvanic process is stopped before the thickness of the metal pattern 4′ reaches the thickness of the resist 3. Next, see FIG. 1d, the resist 3 is removed and then at least x nm of the thin metal layer 2 and of the metal pattern 4′ is removed by sputter etching. By doing this, the plating base 2 on the substrate 1 is removed and a metal structure 4 with thickness D is created. Note that the thin metal layer 2 is still present underneath the metal structure 4. Preferably, the thin metal layer 2 and the metal structure 4 comprise the same metal, like for example copper. As result of the negative slopes of the resist 3, the metal structure 4 has been created with sloped sidewalls 44.

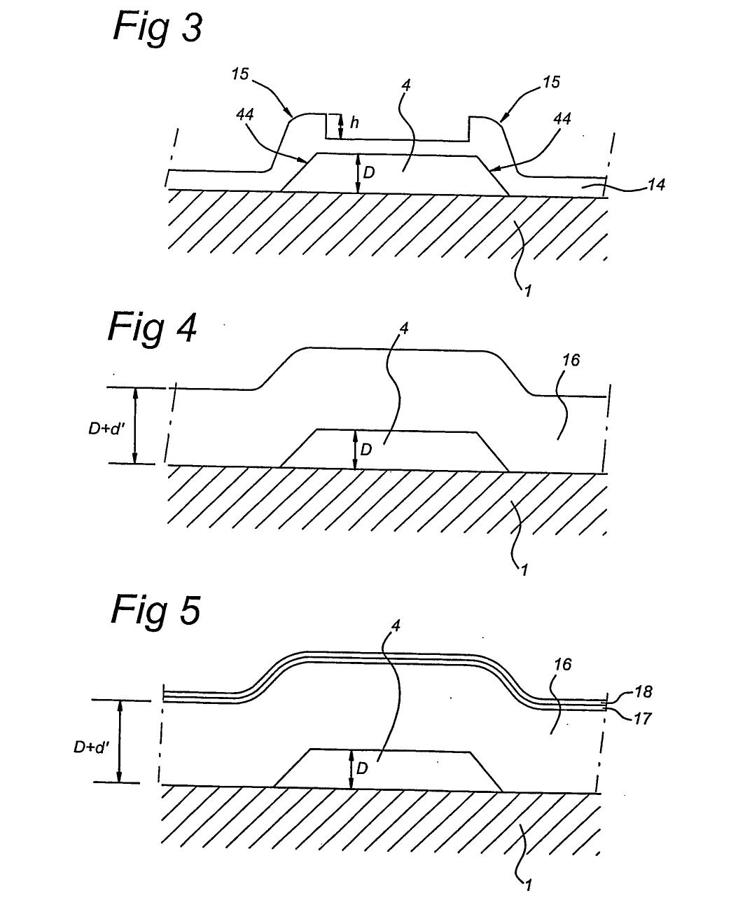

FIG. 2 shows the device after deposition of aluminumoxide 13 on top of the metal structure 4 and the substrate 1. In the following, the thin metal layer 2, like in FIG. 1, is no longer shown. In a next step, the device is etched using a wet etchant bath, e.g. H₃PO₄. The result is shown in FIG. 3. In a remaining aluminumoxide layer 14 walls 15 are formed, just above the sloped sidewalls 44 of the metal structure 4. This is due to a slower etching rate as described above. The height difference between the top of the walls 15 and the top surface of the oxide covering the flat part of the metal structure 4 is called h. To obtain this height h, at least a thickness d, where d≧h has to be deposited.

In another embodiment of the invention the method comprises three more steps, directly after the step of depositing aluminumoxide. In this embodiment, an alumiumoxide 16 is deposited on the metal structure 4. In this embodiment, the thickness of the aluminumoxide 16 is larger than the thickness D of the metal structure 4, i.e. D+d′, with d′>0. FIG. 4 shows a cross-sectional view of a device after deposition of the aluminumoxide 16. Compared to thickness d of the aluminumoxide layer 13 in FIG. 2, the thickness (D+d′) of the aluminumoxide layer 16 in FIG. 4 is larger, for example 8 μm. Then, in a next step a thin non-transparent film 17, like for example molybdenum, is deposited on top of the aluminumoxide 16. Next, a thin aluminumoxide layer 18 is deposited on top of the non-transparent film 17. The result is shown in FIG. 5.

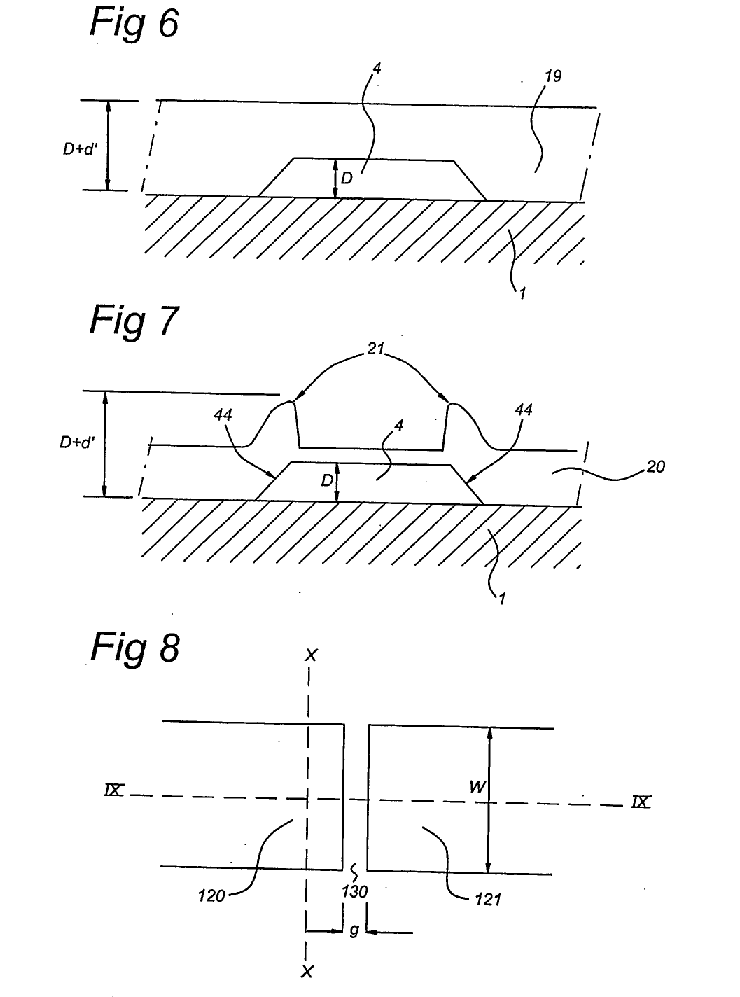

The non-transparent film 17 functions as an optical tool for polishing the aluminumoxide 16 until all non-transparent film 17 is removed. This leaves a flat aluminumoxide 19 as can be seen in FIG. 6. After polishing the aluminumoxide 16, the device is etched using a wet etchant bath. A cross-sectional view of the result is shown in FIG. 7. FIG. 7 shows a aluminumoxide layer 20, comprising aluminiumoxide walls 21, just above the sloped sidewalls 44 of the metal structure 4.

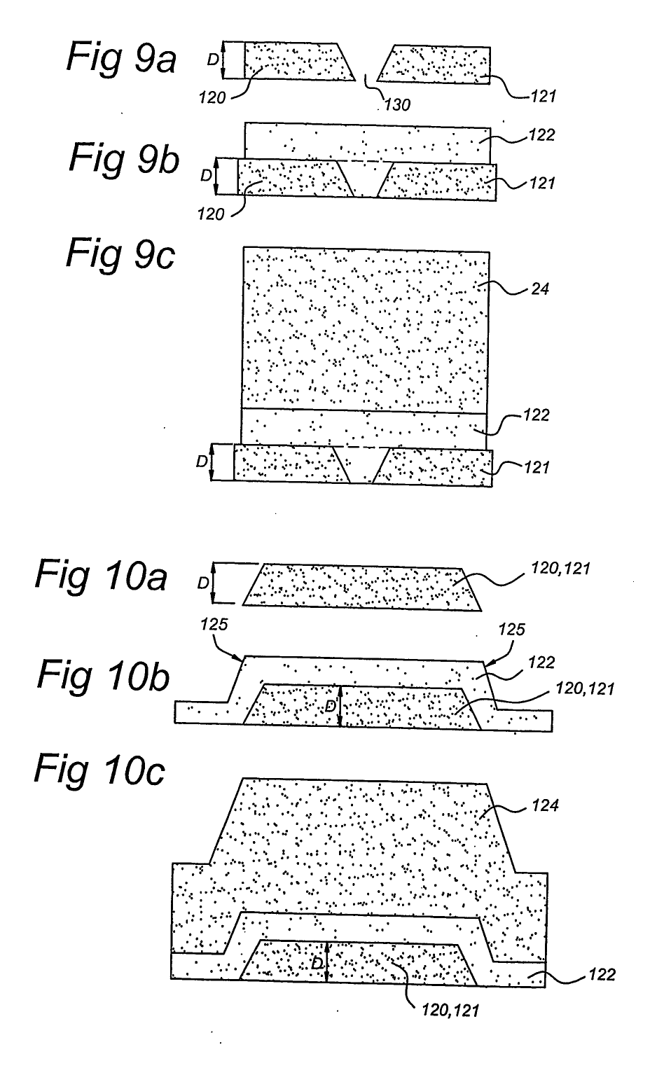

In an embodiment of the invention, the metal structure 4 comprises at least two electrodes. FIG. 8 shows a top view of two separate electrodes 120, 121. When different electrodes have to be biased differently, a small gap 130 between the electrodes is required, see FIG. 8. Preferably the width g of the gap 130 is much smaller than the width of the electrodes w and the thickness D of the electrodes 120, 121, see FIGS. 7 and 8. In an embodiment, the self-aligned structures 15, 21 form sidewalls of microfluidic channels in a microfluidic device. The electrodes 120, 121 can be used to control fluids in the microfluidic channels fabricated on top of the respective electrodes 120, 121. In this case, the aluminiumoxide walls 15, 21 function as sidewalls of the microfluidic channels. However, without any extra processing steps in the method described above, one (or two) non-etching aluminumoxide wall(s) would arise at the gap 130, separating the two channels that are fabricated on top of the electrodes 120 and 121. In an embodiment of the invention, this problem is solved by adding an extra oxide 122, which has a planarization effect, e.g. SiON. FIGS. 9a, 9b and 9c show cross-sectional views of the gap 130 between the two electrodes 120, 121 at the line IX-IX of FIG. 8 in three stages of the fabrication process. FIG. 9b shows the extra oxide 122 that fills the gap 130 and covers the electrodes 120, 121. FIG. 9c shows the device after sputtering an aluminumoxide layer 124. FIGS. 10a, 10b and 10c show cross-sectional views of one of the electrodes 120, 121 at the line X-X of FIG. 8 in the three stages of the fabrication process. As can be seen from FIG. 10b, the oxide layer 122 is sloped (see sloped walls 125) as are the sidewalls of the electrode 120. This sloped oxide will have the same effect on the wall forming process as the sloped sidewalls of the electrodes 120, 121 without the extra oxide 122. This means, aluminumoxide walls (not shown, but like the walls 15 in FIG. 3) will occur above the sloped walls 125, after etching part of the aluminumoxide layer 124. Since the distance g between the electrodes 120, 121 is much smaller than the width w of the electrodes, the sidewall of the covering oxide 122 at the sidewalls of the gap 130 will also be sloped, resulting in a correct connection of the aluminumoxide walls in the axial direction of the channel.

The same method can be applied for junctions consisting of more than two electrodes. As long as the gap 130 between the metals is much shorter than the width w of the electrodes 120, 121, the oxide 122 will fill the gap 130.

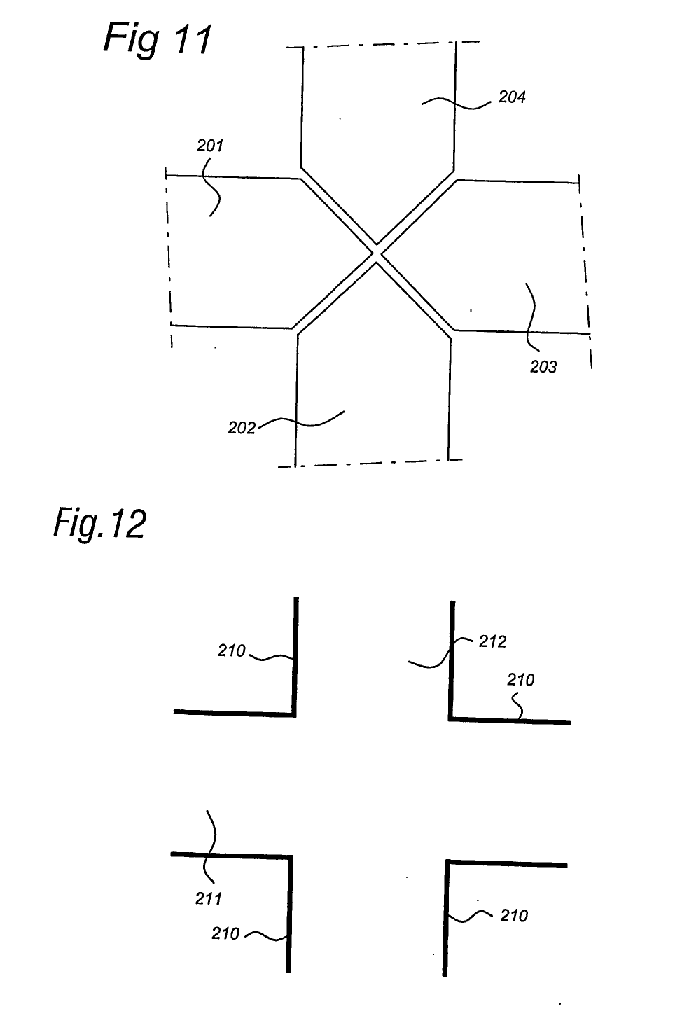

FIG. 11 shows a junction of four electrodes 201, 202, 203, 204, which can be made by using the above-described steps. FIG. 12 shows the resulting walls 210 in the aluminumoxide layer on top of the electrodes 201, 202, 203, 204 after etching part of the aluminumoxide, according to the invention. The walls 210 form an intersection of two (microfluidic) channels 211 and 212.

The microfluidic channels described above, can be used e.g. in microfluidic devices to select, modify and analyze liquids on a small scale. Examples of such devices are the so-called “Lab-on-a-chip” systems, see for example A. Manz, N. Graber and H. M. Widmer, Miniaturized total chemical analysis systems: A novel concept for chemical sensing, Sensors and Actuators B1, pg. 244-248 (1990), which can be used in point of care diagnostics (POCD). In these applications electrical means are often anticipated for displacing the fluids (e.g. electrowetting, electro-osmosis). With the present invention, the electrodes 120, 121 and the channels can be fabricated with a single mask step. After the channels have been formed in the etching process, a glass or polymeric plate can be placed on top of the sample, creating closed channels. It is also possible to cover the glass or polymeric plate homogeneously with Indium Tin Oxide (ITO), so that this can be used to define a reference potential (e.g. ground potential). For this application, the process to fill the small gap between electrodes with an insulator is essential. If this can be achieved, a continuous channel is defined on the sides of the segmented electrodes and the fluid can be displaced by applying the right biases to the proper segments.

In yet another embodiment of the invention, the metal structure comprises a plurality of separate electrodes 120, 121 for use in a reflective electrowetting or electrophoretic display. After etching, a separate electrode is surrounded by Al₂O₃ pixel walls that can confine the switchable medium. An example of such a display that could benefit from this principle is a reflective electrowetting display where the switching medium is an oil/water stack. Also other display principles, such as an electrophoretic display may benefit from this invention.

Finally, the invention could be used to define pixels in a field emitting display (FED).

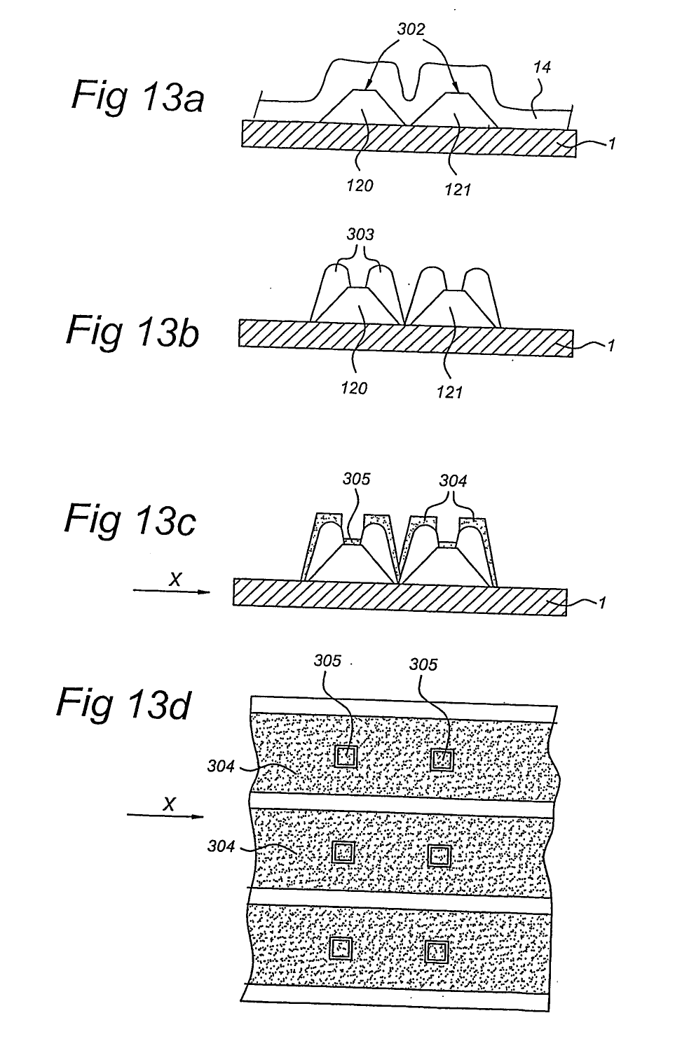

For such a device, closely positioned electrode structures 120, 121 are fabricated with very small flat surfaces, see FIG. 13a. These electrode structures 120, 121 are covered by an aluminiumoxide layer. Next, the aluminumoxide layer on the electrodes 4 is removed completely, except for non-etching pillars 303, see FIG. 13b. Next, a conducting layer is deposited by way of sputtering or evaporation techniques in such a way that it is only situated on tips and outer wallsides of the pillars 303 and on top of the electrodes 120, 121, see FIG. 13c. The conducting layer 304 situated on the pillars 303 function as FED-gates 304. These FED-gates 304 are spatially separated from the conducting layer portions 305 on top of the electrodes 120, 121, which function as FED emitters 305. This separation can for instance be achieved by using a mask deposition, but other methods may be possible as well.

In a FED the FED-gates 304 are connected in order to be able to contact these electrodes to a voltage source. A possible electrode configuration is shown in FIG. 13d, which shows a top view of the FED electrodes 304, 305. This configuration is fabricated by depositing a conducting layer and the outer wallsides of the pillars 303, but only in an x-direction, as shown in FIGS. 13c and 13d. On the surface of the device structured lines appear, to allow passive matrix addressing with one or multiple lines per pixel.

The structure shown in FIG. 13d is only an example; it should be clear that many other configurations are possible as well. As a result, an emitting structure (the original electrodes 120, 121) and a gate 304 on top of the pillars 303 are created. Note that the flat electrodes 120, 121 will exhibit no field enhancement, and therefore require rather high voltages. If the electrodes 120, 121 are made very small, the field enhancement could possibly be retained. Moreover, for small structures one could use multiple emitting structures per pixel, which will result in an improved homogeneity of the pixels across the display.

While the invention has been described in connection with preferred embodiments, it will be understood that modifications thereof within the principles outlined above will be evident to those skilled in the art, and thus the invention is not limited to the preferred embodiments but is intended to encompass such modifications.

1. Method of manufacturing a device on a substrate, comprising:
Depositing a metal layer with a thickness x on the substrate;
Depositing a resist layer;
Patterning of the resist layer using lithographic techniques, leaving a resist pattern with negative slopes;
Depositing metal using a galvanic process;
Removing the resist pattern;
Sputter etching of the metal and the metal layer to remove said metal layer and provide a metal structure with sloped sidewalls;
Depositing a first layer of a metal oxide; in particular aluminumoxide
Forming self-aligned structures above the sloped sidewalls of the metal structure by etching the first layer of metal oxide until a predetermined thickness of metal oxide above the metal structure remains.

2. Method according to claim 1, characterized in that the depositing of the first layer of aluminumoxide is directly followed by:
Depositing a non-transparent film on top of the first layer of aluminumoxide;
Depositing a second layer of aluminumoxide on top of the non-transparent film;
Polishing the aluminumoxide until all non-transparent film is removed.

3. Method according to claim 1, characterized in that before the depositing of the first layer of aluminumoxide, an oxide layer is deposited, in such a way that the oxide layer fills gaps between parts of the metal structure.

4. Method according to claim 3, characterized in that the oxide layer comprises SiON.

5. Method according to claim 1, characterized in that the metal structure comprises at least two electrodes of the device, the at least two electrodes defining a gap in between the at least two electrodes.

6. Method according to claim 1, characterized in that the self-aligned structures form sidewalls of microfluidic channels in a microfluidic device.

7. Method according to claim 1, characterized in that said metal structure comprises a plurality of separate electrodes.

8. Method according to claim 7, characterized in that the device is a reflective electrowetting or electrophoretic display.

9. Method according to claim 7, characterized in that the device is a Field Emitting Device and said first layer of aluminumoxide is etched until all of the aluminumoxide above the separate electrodes is gone, said method also comprising:
Depositing a conducting layer on tops and outer sidewalls of the self-aligned structures and on top of the separate electrodes in such a way that electrically separated gates and emitters are created.

10. Microfluidic device fabricated by using the method according to claim 6.

11. Electrowetting display fabricated by using the method according to claim 7.

12. Electrophoretic display fabricated by using the method according to claim 7.

13. Field emitting device fabricated by using the method according to claim 9.
